(19) United States
(12) Patent Application Publication
(10) Pub. No.: US 2025/0250158 A1
(43) Pub. Date: Aug. 7, 2025

(54) DIRECTIONAL MICROPHONE

(71) Applicant: TEXAS INSTRUMENTS INCORPORATED, Dallas, TX (US)

(72) Inventors: Xiaoyu Niu, Austin, TX (US); Bichoy Bahr, Allen, TX (US); Udit Rawat, Allen, TX (US); Baher Haroun, Allen, TX (US)

(21) Appl. No.: 18/986,655

(22) Filed: Dec. 18, 2024

Related U.S. Application Data
(60) Provisional application No. 63/548,965, filed on Feb. 2, 2024.

(51) Int. Cl. B81B 3/00; H04R 1/32

(52) U.S. Cl. CPC B81B 3/0051; H04R 1/326; B81B 2201/0257; B81B 2203/0118; B81B 2203/0127; B81B 2203/0307; B81B 2203/0315; B81B 2203/04; B81B 2207/012; B81B 2207/015; H04R 2201/003

(57) ABSTRACT

An apparatus is described which comprises a substrate including a cavity and first and second anchors. In at least one example, the apparatus comprises a cantilever including a first portion, a second portion, and a third portion, the first portion coupled between the second and third portions, the first portion coupled to the first and second anchors and is suspended over the cavity, and a length of the first portion along a dimension is shorter than respective lengths of the second and third portions along the dimension.

### CLAIM OF PRIORITY

This application claims priority to U.S. Provisional Patent Application No. 63/548,965, filed on Feb. 2, 2024, titled “Directional Microphone,” which is incorporated by reference in its entirety for all purposes.

### BACKGROUND

An audio device, such as a microphone, converts mechanical energy (e.g., vibration) to electrical energy. Ambient noise significantly impacts the quality of audio recording from microphones. Ambient noise level in lots of application environments such as automotive applications can significantly exceed the intrinsic noise of microphones, which prohibit quality audio recording, irrespective of the microphones used. Directional microphones can mitigate ambient noise and improve recording quality in noisy environments. Directional microphones can also improve performance for wake-on command/voice activated systems by eliminating ambient noise.

### BRIEF DESCRIPTION OF DRAWINGS

The examples will be understood more fully from the detailed description given below and from the accompanying drawings, which, however, should not be taken to limit the disclosure to the specific examples, but are for explanation and understanding only.

FIG. 1 is a schematic illustrating an audio system for a directional microphone, in accordance with at least one example.

FIG. 2A is a schematic illustrating a top view of a directional microphone with tapered cantilevers anchored in a middle portion of the unidirectional microphone, in accordance with at least one example.

FIG. 2B is a schematic illustrating a side view of the directional microphone of FIG. 2A, in accordance with at least one example.

FIG. 2C is a schematic illustrating a side view of the middle portion of FIG. 2A, in accordance with at least one example.

FIG. 2D is a schematic illustrating an isometric view of the middle portion of FIG. 2A, in accordance with at least one example.

FIG. 2E is a schematic illustrating an isometric view of the middle portion of FIG. 2A, in accordance with another example.

FIG. 3A is a schematic illustrating a side view of the directional microphone of FIG. 2A with a lateral sound direction, in accordance with at least one example.

FIG. 3B is a schematic illustrating a side view of the directional microphone of FIG. 2A with a perpendicular sound direction, in accordance with at least one example.

FIG. 4A is a schematic illustrating a side view of the directional microphone of FIG. 2A with additional mass on the middle portion to improve sensitivity, in accordance with at least one example.

FIG. 4B is a schematic illustrating a side view of the unidirectional microphone of FIG. 2A with additional mass on the middle portion and outer edges of the tapered cantilever to improve sensitivity, in accordance with at least one example.

FIGS. 5A, 5B, 5C, and 5D are schematics of the tapered cantilever under rotational and bending configurations and their associated stiffness distributions, in accordance with some examples.

FIGS. 6A, 6B, 7A, and 7B are schematics illustrating a side view of an audio system including a directional microphone, in accordance with at least one example.

FIG. 8 is a schematic illustrating a top view of an ambient microphone, in accordance with at least one example.

FIGS. 9A and 9B are schematics illustrating side views of the ambient microphone of FIG. 8, in accordance with at least one example.

FIG. 10A is a schematic illustrating a top view of a directional microphone with hammerhead cantilevers anchored in a middle portion of the directional microphone, in accordance with at least one example.

FIG. 10B is a schematic illustrating a top view of a directional microphone with curvingly tapered cantilevers anchored in a middle portion of the directional microphone, in accordance with at least one example.

FIGS. 11A, 11B, and 11C are schematics of the ambient microphone showing distributions of bending and rotational stiffness, in accordance with at least one example.

### SUMMARY

In at least one example, an apparatus is provided that comprises a substrate including a cavity and first and second anchors. The cantilever includes a first portion, a second portion, and a third portion. The first portion is coupled between the second and third portions. The first portion is further coupled to the first and second anchors and is suspended over the cavity. The length of the first portion along a dimension is shorter than respective lengths of the second and third portions along the dimension.

In at least one example, a packaged integrated circuit (IC) is provided that includes a package substrate, a die on the package substrate, and a case on the package substrate and enclosing the die, the case including multiple openings. In at least one example, the die includes a first substrate including a cavity, first and second anchors, and a cantilever. The cantilever includes a first portion, a second portion, and a third portion. The first portion is coupled between the second and third portions. The first portion is further coupled to the first and second anchors and is suspended over the cavity. The length of the first portion along a dimension is shorter than respective lengths of the second and third portions along the dimension.

### DETAILED DESCRIPTION

Disclosed herein is a transducer device with a plurality of tapered cantilevers coupled to (and anchored to) at least two posts or anchors in a middle region of the transducer device. The at least two posts may be silicon posts and part of a substrate and provide a point of pivot for the plurality of tapered cantilevers. In at least one example, a tapered cantilever has two opposite edges with different dimensions, where a first edge with shorter dimension or length is attached to the post while a second edge with longer dimension and opposite to the first edge is not attached to any substrate. The plurality of tapered cantilevers forms a butterfly shaped membrane with two flaps on either side of the two posts or anchors. The two flaps are symmetrical in shape. The butterfly shaped membrane may have straight or curved edges.

The transducer device is configured as a unidirectional sensor wherein the two flaps of the plurality of tapered cantilevers either rotate or bend along the at least two posts or anchors in the middle region. The two flaps rotate along the two pivots or anchors based on an input pressure from sound being substantially parallel to the two flaps. This causes a net differential voltage across the two flaps. The net differential voltage is processed to generate a digital signal representing the input sound. The butterfly shaped membrane with rocking mode is mostly sensitive to pressure differential and implemented in piezoelectric bimorph technology. The two flaps bend on either side of the two posts or anchors based on the input pressure from the sound being substantially perpendicular to the two flaps. The perpendicular pressure causes a net zero differential voltage across the two flaps and thus no sound being detected. Accordingly, the transducer device can have a higher sensitivity for pressure (and sound) coming from a particular direction (e.g., perpendicular to the flaps) versus pressure (and sound) coming from another direction (e.g., parallel to the flaps), which allows the transducer device to operate (or to be part of) a directional sensor.

In at least one example, two butterfly shaped membranes are anchored in the middle region. Such a configuration allows for sensing input pressure in two different parallel directions that are orthogonal to one another while discriminating against perpendicular input pressure. This allows for implementing an ambient sensor, in accordance with at least one example. In at least one example, a processing circuit or an integrated circuit is coupled to the transducer device and configures/operates the transducer device to provide a particular function, such as a directional microphone (e.g., audio sensor).

The examples discussed herein can provide various advantages. For instance, stress enhancement or amplification is achieved by anchoring shorter edges of the tapered cantilevers to at least two posts in the middle region. The butterfly shape enhances the sensitivity to pressure gradient because it reduces the stiffness at the anchoring point, while creating a large area at the large pressure region of the flaps. The butterfly shape resists bending movement and facilitates rotational movement along the two posts or anchors. The tapered configuration of the butterfly shaped membrane increases sensitivity near the two posts or anchors. The middle region of the butterfly shaped membrane increases coupling between the two flaps. The discrimination in favor of rotational movement of the flaps can also be achieved by adding a mass over the middle region. In at least one example, the discrimination in favor of rotational movement of the flaps is achieved by adding mass at the outer edges of the two flaps away from the middle region.

Moreover, the bimorph structure of the butterfly shaped membrane enhances the energy coupling, which results in better sensitivity and improved signal-to-noise (SNR) over unimorph designs. Stress enhancement or amplification improves the electromechanical coupling and the efficiency of transduction (conversion between mechanical and electrical energies). In the case where the tapered cantilevers are part of a sensing device (e.g., a microphone, an accelerometer, etc.), the improved efficiency of transduction can improve the SNR and sensitivity and allow the transducer device to have a reduced footprint (e.g., compared with a beamformer array).

Also, by anchoring or clamping the shorter edges of the plurality of tapered cantilevers to the at least two posts, the area of the transducer device can be further reduced as shorter or smaller tapered flaps can be used because of stress amplification, which can further reduce the footprint of the transducer device. Also, the tapered flaps of the plurality of tapered cantilevers can have smaller weights, which can improve the overall structural integrity of the cantilever as the flaps are less prone to break off due to the mechanical stress caused by their weights. Other technical effects will be evident from various examples described herein. Here, the same reference numbers or other reference designators are used in the drawings to designate the same or similar (either by function and/or structure) features.

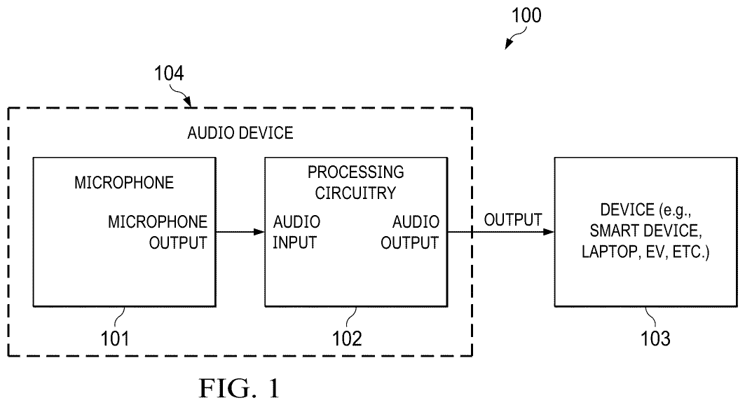

FIG. 1 is a schematic illustrating a system 100 with tapered cantilevers for a directional microphone, according to at least one example. System 100 may comprise a microphone 101, a processing circuit 102, and a device 103. Microphone 101 and processing circuit 102 can be part of an audio system 104. In at least one example, microphone 101 comprises a micro-electromechanical system (MEMS) or a nano-electromechanical system (NEMS) that converts mechanical energy from incident sound waves. Microphone 101 can output an analog electrical signal on a microphone output to an audio input of processing circuit 102.

In at least one example, microphone 101 comprises a plurality of tapered cantilever flaps that includes electrodes. In at least one example, the plurality of tapered cantilever flaps is a set of bimorph cantilever flaps with shorter edges attached to at least two posts or anchors. The plurality of tapered cantilever flaps can rotate or bend along the two posts or anchors responsive to external sound waves and generates electrical signals representing the sound waves. The output from the plurality of tapered cantilever flaps of microphone 101 can be coupled to an audio input of processing circuit 102 via a microphone output. The audio output of processing circuit 102 can be coupled to device 103 and can provide a processed audio output (e.g., digital signal representing audio sensed by microphone 101) to device 103.

In at least one example, processing circuit 102 comprises (or is part of) an integrated circuit which includes logic and or circuit to convert the audio input in an analog or acoustic domain (e.g., an analog signal) to the audio output in a digital domain or electrical domain (e.g., digital signal). Device 103 is any suitable client that uses the audio output from audio system 104. Examples of device 103 include a smart device, a smart phone, a tablet, an electric vehicle, a wearable device, a computer, etc.

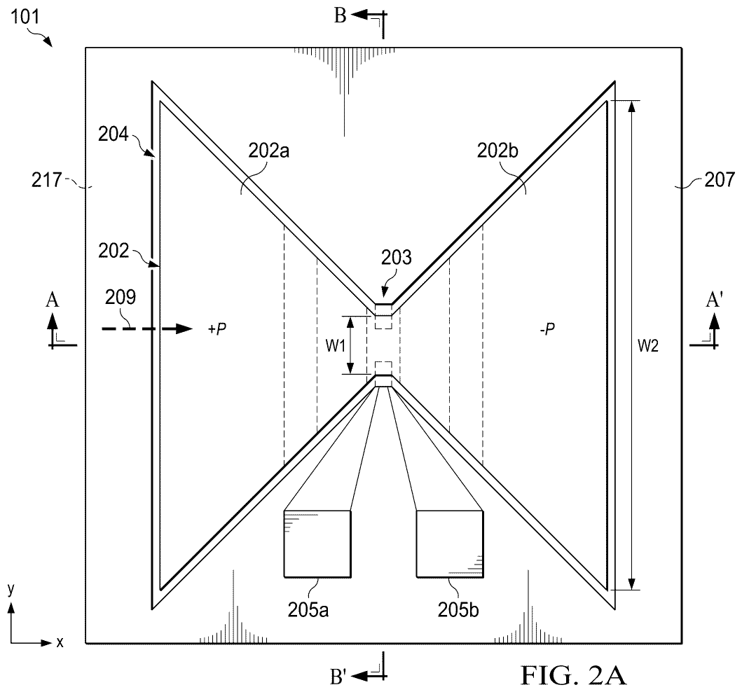

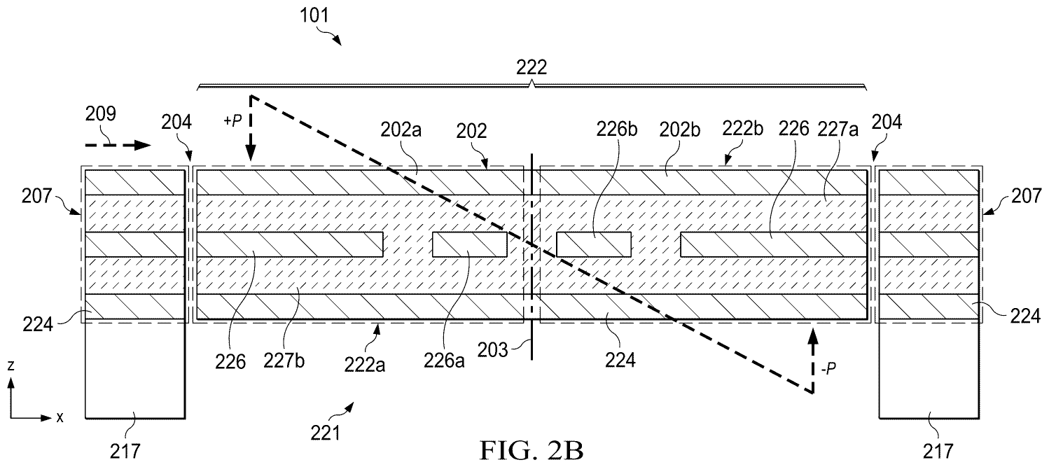

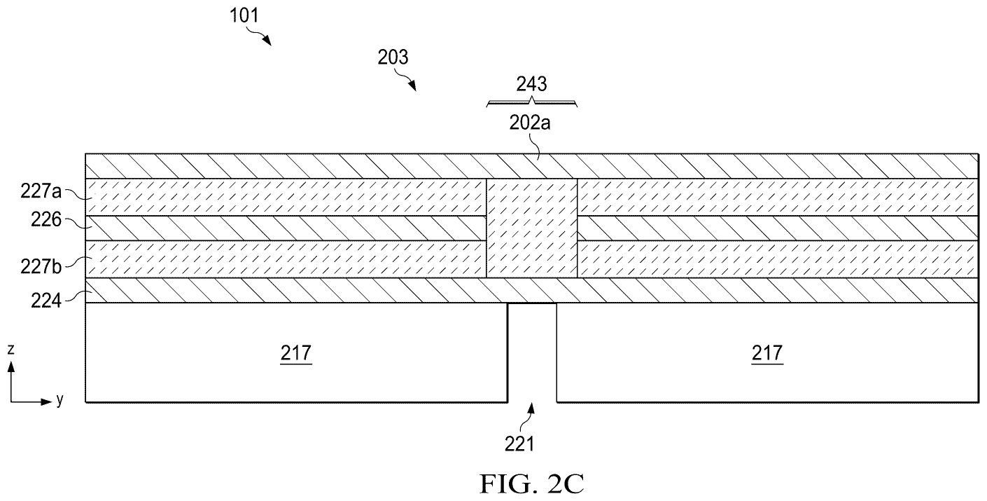

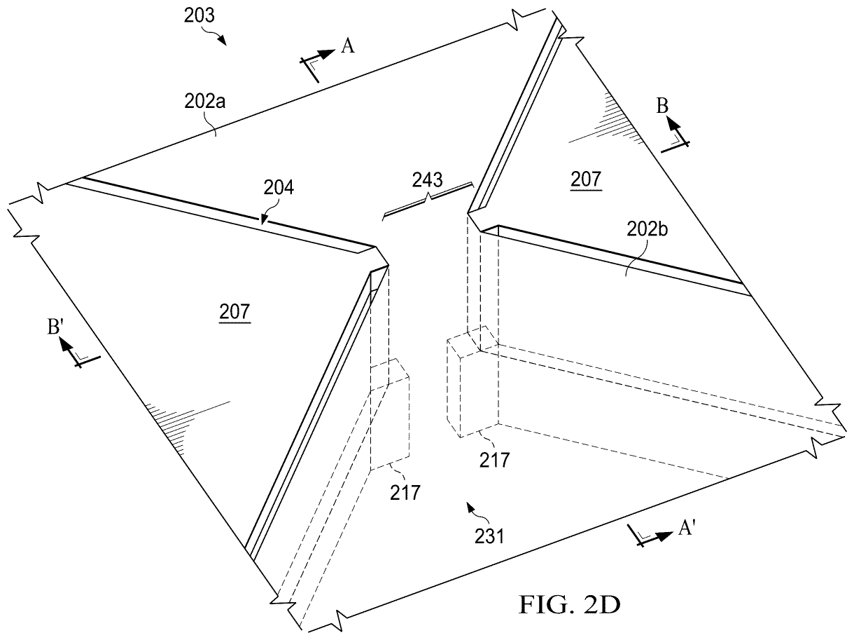

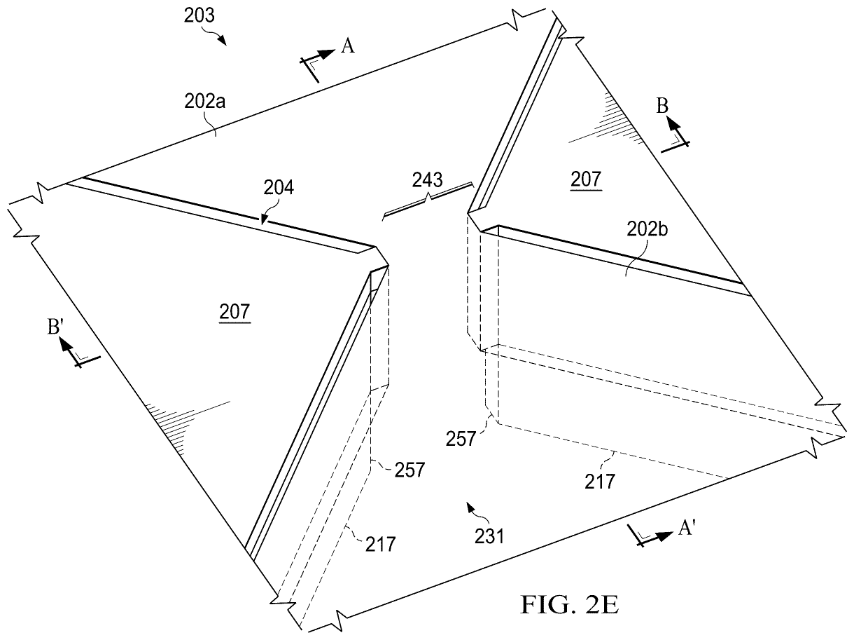

FIG. 2A is a schematic illustrating a top view of a directional microphone 101 with tapered cantilevers anchored in a middle portion of directional microphone 101, in accordance with at least one example. FIG. 2B is a schematic illustrating a side view of the directional microphone of FIG. 2A, in accordance with at least one example. FIG. 2C is a schematic illustrating a side view of the middle portion of FIG. 2A, in accordance with at least one example. FIG. 2D is a schematic illustrating an isometric view of the middle portion of FIG. 2A, in accordance with at least one example.

In some examples, microphone 101 comprises a butterfly-shaped membrane 202 configured as a cantilever with a first portion 202a, a second portion 202b, and a third portion 203 (middle region). The length W1 of third portion 203 along a y-dimension is shorter than respective lengths W2 of the first and second portions 202a and 202b along the y-dimension. First portion 202a and second portion 202b are flaps that have tapered shapes with shorter or narrow edges coupled to third portion 203 while longer edges at distil ends. First portion 202a and second portion 202b form a top electrode while third portion 203 forms an anchor and couples first portion 202a and second portion 202b. In the examples shown in FIG. 2A, the flaps linearly increase in length along the y-dimension away from the anchor (e.g., along the x-dimension) to follow pressure increase and create uniform bending force, reducing mass loading to achieve higher resonance frequency, while maintaining good sensitivity. In other examples, the flaps may increase non-linearly (e.g., according to a quadratic function, an exponential function, etc.) in length along the y-dimension away from the anchor.

In at least one example, butterfly-shaped membrane 202 is part of cantilever 222 having cantilever flaps 222a and 222b which are piezoelectric bimorph as illustrated in FIG. 2B. FIG. 2B shows cross-section along a line AA′. Microphone 101 further includes pads 205a and 205b that are electrically coupled to the piezoelectric bimorph near third portion 203. The perimeter of butterfly-shaped membrane 202 is surrounded by a gap 204 except for some portion of third portion 203 that is configured as anchors. Gap 204 separates flaps 222a and 222b from a fixed portion 207 which may comprise a piezoelectric bimorph or a substrate (e.g., silicon). The rest of cantilever 222 is suspended over a cavity 221. Gap 204 allows cantilever flaps 222a and 222b to bend or rotate along third portion 203 as sound waves interact with cantilever 222. Here, third portion 203 acts as a pivot along first and second anchors comprising substrate 217. Microphone 101 further includes substrate 217 that supports fixed portion 207. Substrate 217 includes cavity 221 and first and second anchors which are portions of substrate 217 as shown in FIG. 2C. FIG. 2C shows cross-section along a line BB′.

FIG. 2D shows third portion 203 where cantilever 222 can be anchored on a pair of silicon structures comprising substrate 217 spaced apart from the pivot. As shown, middle portion 243 of cantilever 222 at intersection of line AA′ and line BB′ axes is suspended/floating. Such arrangements allow middle portion 243 to be stiff and facilitate rocking of cantilever around the pivot. The bimorph flap layers are mostly continuous at the anchoring of the butterfly shaped structure. In at least one example, not just the underlying silicon or substrate 217 is continuous and used as anchor, but the bimorph flaps are the main anchor. In at least one example, silicon 217 underneath is mostly etched away to allow the rocking motion as opposed to the bending motion.

Microphone 101 is configured as a directional sensor where cantilever flaps 222a and 222b either rotate or bend in the z-direction along first and second anchors comprising substrate 217 in third portion 203. Here, the anchors in middle portion 243 are primarily the bimorph flaps of cantilever flaps 222a and 222b and partly from substrate 217 as described before. Cantilever flaps 222a and 222b can rotate along first and second anchors comprising substrate 217 in third portion 203 based on an input pressure from sound 209 being, for example, substantially parallel to, or having a first angle with respect to, cantilever 222. This causes a net differential voltage sensed by pads 204a and 204b. The net differential voltage is processed to generate a digital signal representing the input sound. The butterfly shaped membrane, implemented in piezoelectric bimorph technology, with rocking mode is mostly sensitive to pressure differential +P and −P along the z-direction due to, for example, sound coming from a particular direction. The membrane can also bend around the first and second anchors, but the bending is restricted, and the membrane can be less sensitive to pressure differential along other directions (e.g., along the x or y-directions) that creates the bending, thereby enabling microphone 101 to be a directional sensor.

Cantilever 222 further includes a bottom electrode 224 and a middle electrode layer 226 between first and second portions 202a and 202b of the top electrode. In at least one example, a first piezoelectric material 227a is between first and second portions 202a and 202b of the top electrode and middle electrode layer 226. In at least one example, a second piezoelectric material 227b is between middle electrode layer 226 and bottom electrode 224. In at least one example, first piezoelectric material 227a is same as second piezoelectric material 227b. In at least one example, first piezoelectric material 227a is different from second piezoelectric material 227b. First piezoelectric material 227a has a thickness along a z-direction of t_{piezo} which can be the same thickness for second piezoelectric material 227b or can have different thicknesses. In at least one example, middle electrode layer 226 includes a first electrode portion 226a and a second electrode portion 226b on opposite sides of the pivot and spaced apart from each other. Middle electrode layer 226 may not be a continuous metal layer. Pads 204a and 204b are electrically coupled to first electrode portion 226a and second electrode portion 226b of middle electrode layer 226, respectively.

In at least one example, cantilever 222 is a MEMS or a NEMS, which is fabricated within micron or nanometer dimensions, respectively. Certain MEMS or NEMS technologies may provide several benefits, such as batch fabrication that may lower manufacturing costs, small feature sizes, high resonant frequencies, and improved impedance matching.

In at least one example, first piezoelectric material 227a and second piezoelectric material 227b comprise aluminum nitride (AlN). The thickness of AlN can be configured based on the target performance of cantilever 222. For example, the thickness of AlN is substantially in a range of 200 nm to 500 nm to maximize SNR and sensitivity. While the examples are discussed with reference to AlN, any suitable piezoelectric material may be used. In at least one example, the electrodes (e.g., first and second portions 202a and 202b of the top electrode, bottom electrode 224, and middle electrode layer 226) of cantilever 222 comprise molybdenum (Mo, or “moly,” or any other suitable material for electrodes). In at least one example, fixed portion 207 is a piezoelectric bimorph with layers similar to layers of cantilever 222 but without a cavity under it. Fixed portion 207 sits on substrate 217. In at least one example, fixed portion 207 is substrate 217.

The rotation of cantilever flaps 222a and 222b along the pivot are converted into electrical signal(s) on pads 204a and 204b. In at least one example, one or more electric terminals are coupled to pads 204a and 204b and connected to a sense line which in turn is received by processing circuit 102.

Cross-section along line BB′ in FIG. 2C illustrates third portion 203 and first and second anchors comprising substrate 217 separated by cavity 221. In at least one example, middle electrode layer 226 is removed in third portion 203 and first portion 202a of the top electrode and bottom electrode 224 are separated by the piezoelectric material. In other examples, third portion 203 includes piezoelectric bimorph with layers similar to layers of cantilever 222 where middle electrode layer 226 is continuous in third portion 203. Third portion 203 includes a middle portion 243 that is suspended over cavity 221 and anchored on first and second anchors comprising substrate 217. Middle portion 243 of cantilever 222 couples cantilever flaps 222a and 222b. Here, the first and second anchors are explicit extensions of substrate 217 and/or fixed portion 207. As discussed herein, shorter or narrower edges of first portion 202a and second portion 202b of butterfly shaped membrane 202 are coupled to third portion 203 which allows for rocking or bending motion of cantilever flaps 222a and 222b along first and second anchors comprising substrate 217.

Cantilever flaps 222a and 222b can bend along the z-direction on both side of the two posts or anchors comprising substrate 217 based on equal amount of input pressure being present on both sides of the first and second anchor due to, for example, sound perpendicular to cantilever flaps, or at another angle with respect to cantilever laps that the sensor is to be less sensitive for. The perpendicular pressure causes a net zero differential voltage across the two flaps and thus no sound is detected through pads 204a and 204b. As such, microphone 101 is configured to become more sensitive for sound coming from a first direction (e.g., parallel with the flaps, or at a first angle with respect to the flaps) that creates a pressure difference on both sides of the first and second anchors, and less sensitive for sound coming from a second direction (e.g., perpendicular to the flaps, or at a second angle with respect to the flaps) that creates equal pressure on both sides of the first and second anchors.

FIG. 2E is a schematic illustrating an isometric view of the middle portion of FIG. 2A, in accordance with another example. Here, first and second anchors comprising substrate 217 of FIG. 2D are realized as anchors 257 which are part of fixed portion 207 (e.g., substrate 217 or piezoelectric bimorph) and do not extend as anchor or support structures of fixed portion 207 (e.g., substrate 217 or piezoelectric bimorph) as in FIG. 2D.

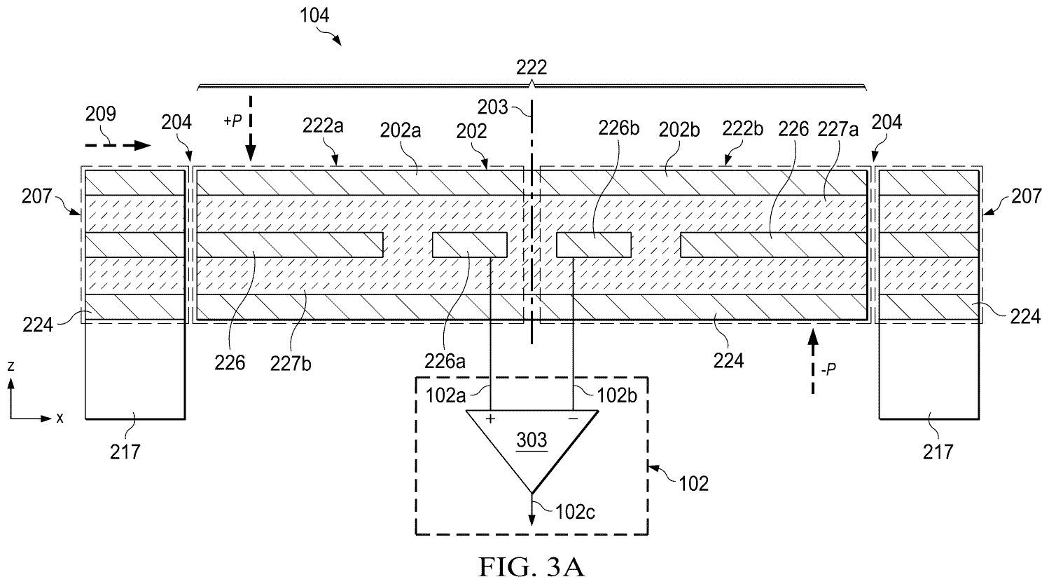

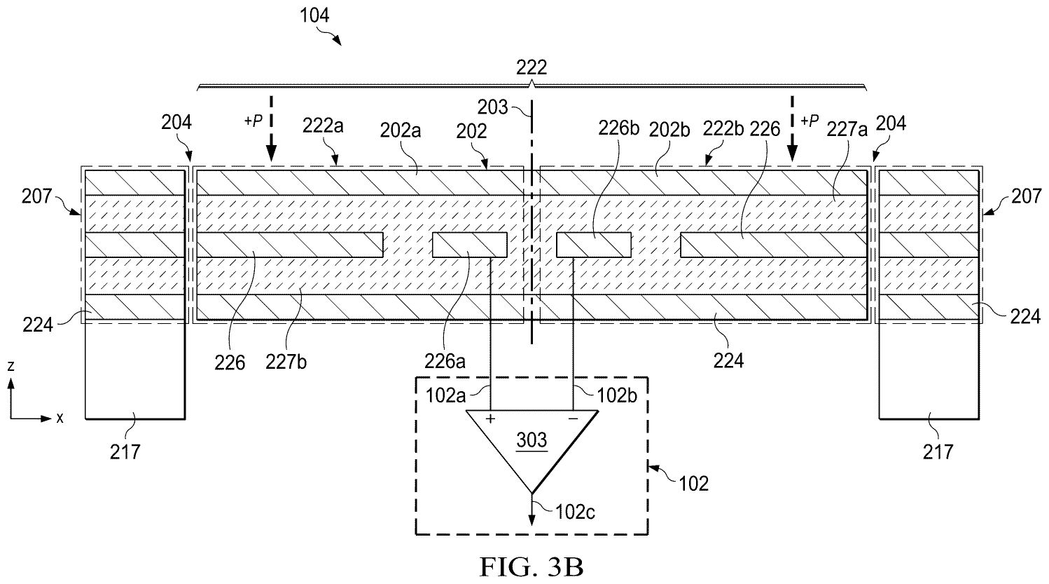

FIG. 3A is a schematic illustrating a side view of the directional microphone of FIG. 2A with a difference amplifier and lateral sound direction, in accordance with at least one example. In-plane sound 209 travelling long the plane of cantilever 222 between outer ends of cantilever flaps 222a and 222b can cause cantilever 222 to rock about the pivot and create a pressure difference around the pivot. A pair of middle electrodes on opposite sides of the pivot are released as first electrode portion 226a and second electrode portion 226b. In at least one example, processing circuitry 102 includes a difference amplifier 303 having a first terminal 102a coupled to first electrode portion 226a and a second terminal 203b coupled to second electrode portion 226b. Difference amplifier 303 includes an output 102c which indicates a net difference between the voltages induced on the first and second terminals 102a and 102b, respectively. Difference amplifier 303 amplifies the voltage difference between the pair of middle electrodes to provide a detection output on output 103c. The detection output can have high sensitivity to in-plane sound.

In this example, cantilever flaps 222a and 222b rotate along first and second anchors comprising substrate 217 in third portion 203 based on an input pressure from sound 209 being parallel to cantilever flaps 222a and 222b (e.g., along the x-direction). This causes a net differential voltage sensed by pads 204a and 204b. The net differential voltage is processed by difference amplifier 303 to generate a digital signal representing the input sound. The butterfly shaped membrane with rocking mode is mostly sensitive to pressure differential +P and −P.

FIG. 3B is a schematic illustrating a side view of the directional microphone of FIG. 2A with a difference amplifier and perpendicular sound direction, in accordance with at least one example. Out-of-plane sound, such as sound travelling orthogonally to the plane of cantilever 222 can cause cantilever flaps 222a and 222b on the two sides of the pivot to band in the same direction, creating equal pressure on both ends of cantilever flaps 222a and 222b. In this example, cantilever flaps 222a and 222b bend along the z-direction on either side of the two posts or anchors comprising substrate 217 based on the input pressure from the sound being perpendicular to cantilever flaps 222a and 222b. The perpendicular pressure +P along the z-direction, on both sides of the anchors, causes a net zero differential voltage across cantilever flaps 222a and 222b and thus no sound being detected through pads 204a and 204b. Here, detection output on output 102c can have a very low sensitivity to the out-of-plane sound. As such, microphone 101 is configured to discriminate between parallel and perpendicular input pressure resulting in a directional sensor.

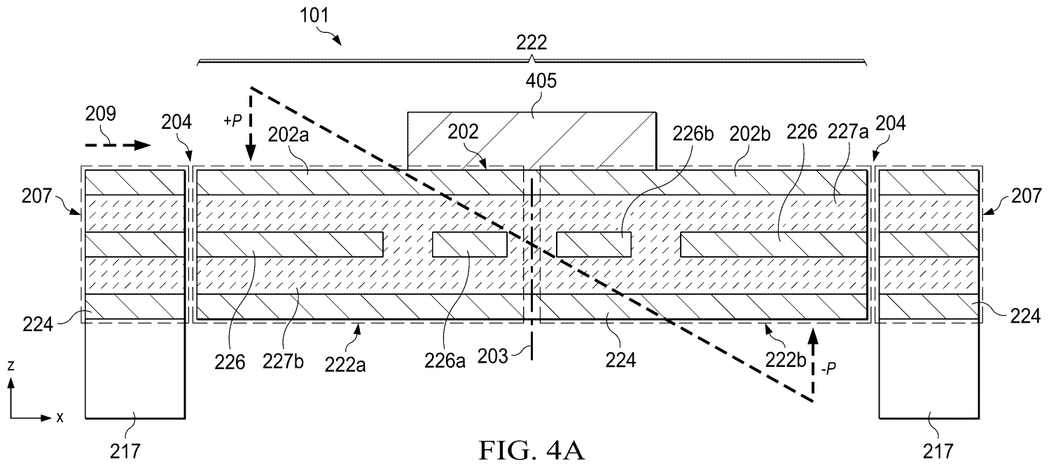

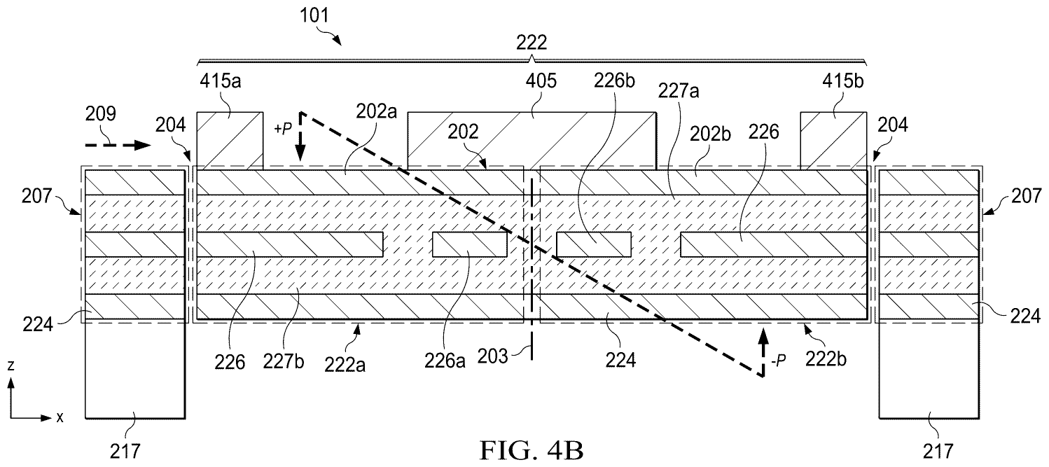

FIG. 4A is a schematic illustrating a side view of the directional microphone of FIG. 2A with additional mass on the middle portion to improve sensitivity, in accordance with at least one example. In at least one example, bending motion of cantilever flaps 222a and 222b is restricted by making third portion 203 stiffer. One way to restrict the bending motion is to add a mass 405 over third portion 203 of cantilever 222. The increased thickness of cantilever 222 in middle portion 243 (e.g., at the center of cantilever 222 and round the pivot) further increases the stiffness to facilitate the rocking motion and to restrict the bending motion. In at least one example, mass 405 is a silicon mass, a metal layer, a bimorph or unimorph piezoelectric material, or a combination of them. In at least one example, rocking motion of cantilever 222 is facilitated by reducing back volume space of directional microphone 101 under cantilever 222. Reducing the back volume space makes it difficult for cantilever flaps 222a and 222b to bend in the same direction due to compression of air which increases the air pressure in the back volume. Rocking motion may not lead to compression of air and increased air pressure in the back volume. In at least one example, rocking motion of cantilever 222 is facilitated by reducing gap 204 between cantilever 222 and the fixed portion 207 to prevent the sound wave from reaching the backside of cantilever 222.

FIG. 4B is a schematic illustrating a side view of the directional microphone of FIG. 2A with additional mass on the middle portion and outer edges of the tapered cantilever to improve sensitivity, in accordance with at least one example. In at least one example, cantilever flaps 222a and 222b can have mass 415a and 415b at the distal ends away from the first and second anchors and near gaps 204. Masses 415a and 415b can maintain the gap distance during the rocking motion, which in turn can maintain the lower 3 dB cut off frequency of the directional microphone. In this example, mass 415a and 415b is on first portion 202a and second portion 202b, respectively.

In at least one example, sensitivity of directional microphone 101 can be further improved by not having the first and second portions 202a and 202b (top electrodes), middle electrode layer 226, and bottom electrode 224 at the far ends of cantilever flaps 222a and 222b. The far ends of cantilever flaps 222a and 222b can be piezoelectric material without electrodes, in accordance with at least one example. In one such example, bimorph structure of cantilever flaps 222a and 222b terminates after first and second electrode portions 226a and 226b, respectively.

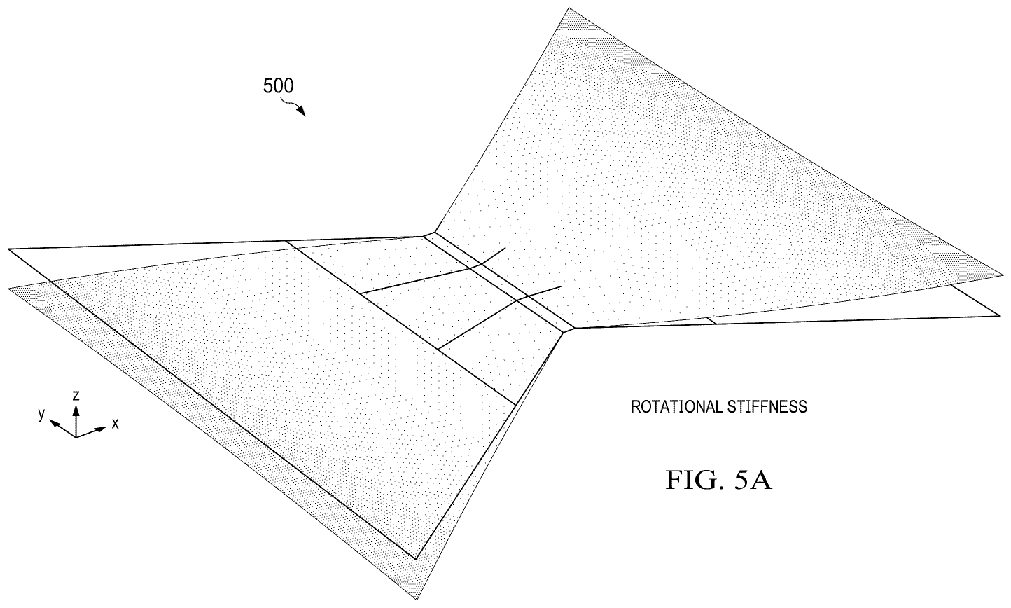

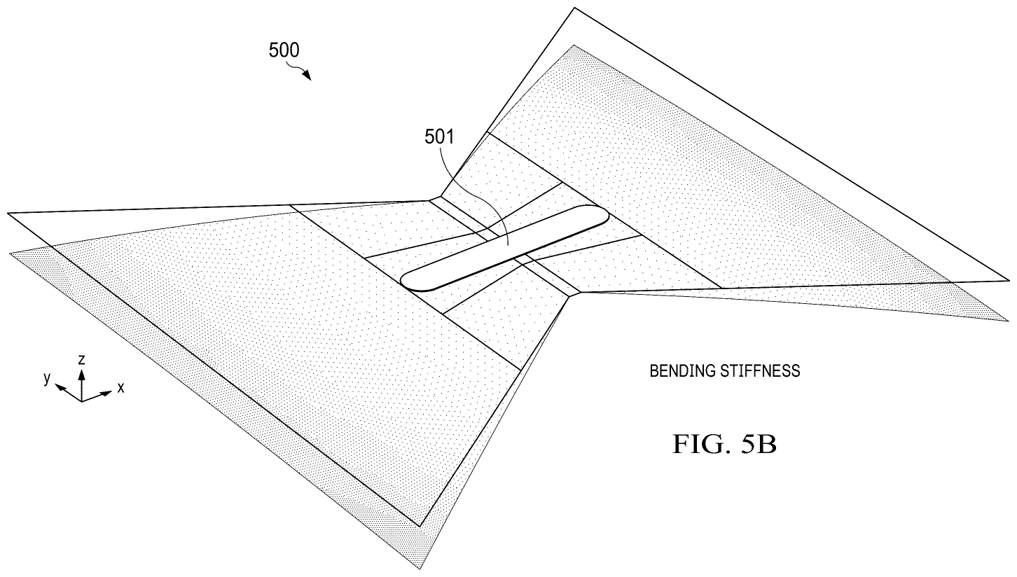

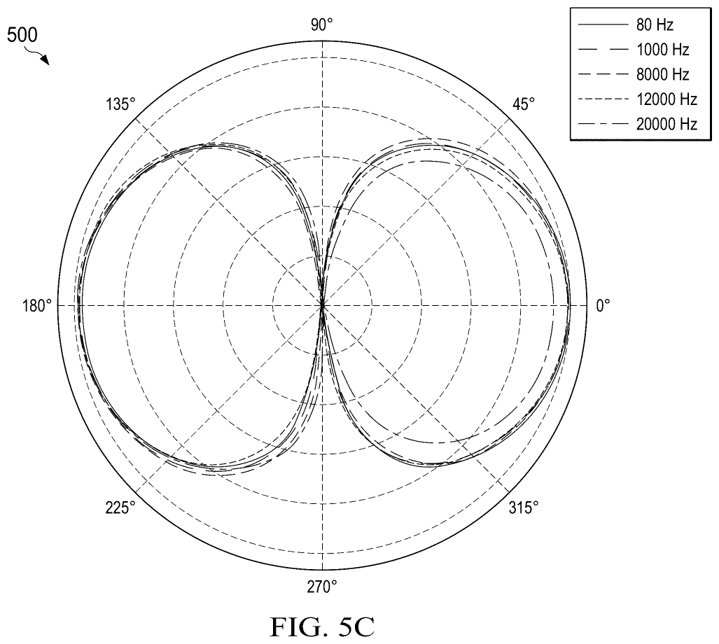

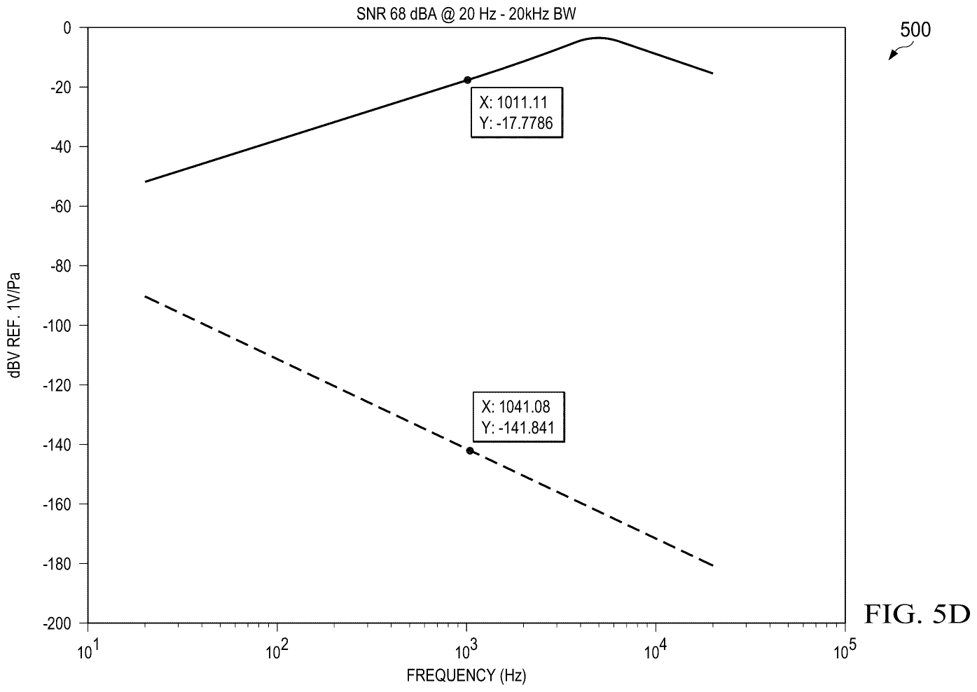

FIGS. 5A-D are schematics of the tapered cantilever under rotational and bending configurations and their associated stiffness characteristics, in accordance with some examples. Here, a set of drawings 500 are illustrated to show rotational stiffness versus bending stiffness. The anchor and the flaps are designed in a way that favors the rotational motion of the directional microphone of FIG. 5A over that of the directional microphone of FIG. 5B. In at least one example, it is much easier to achieve the motion indicated in FIG. 5A whereas the motion of FIG. 5B is stiffer. This is achieved through the exact geometry of the anchor, and the flap structure. In at least one example, a thick metal pad 501 is deposited in the middle of the anchor region to make the motion of FIG. 5B a lot stiffer as compared to that of FIG. 5A.

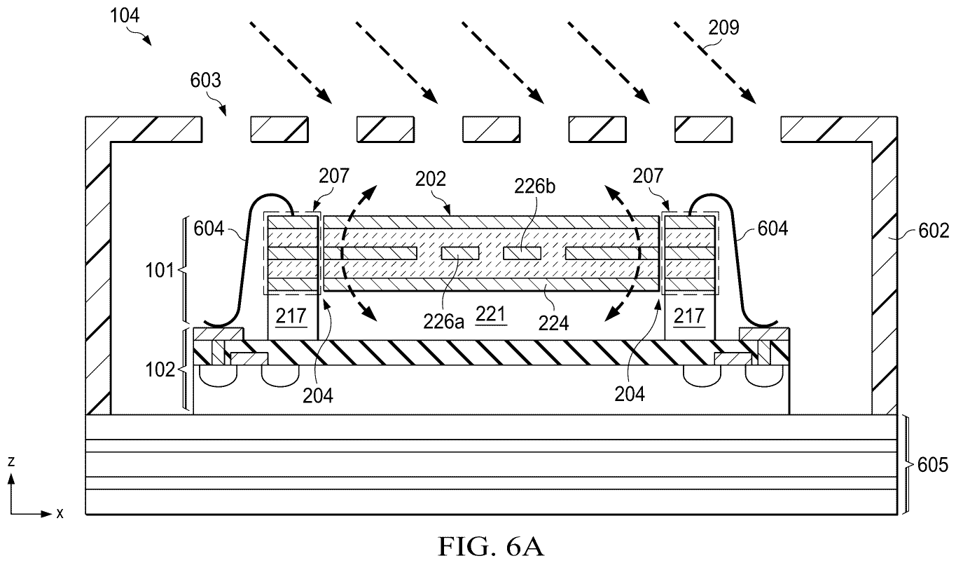

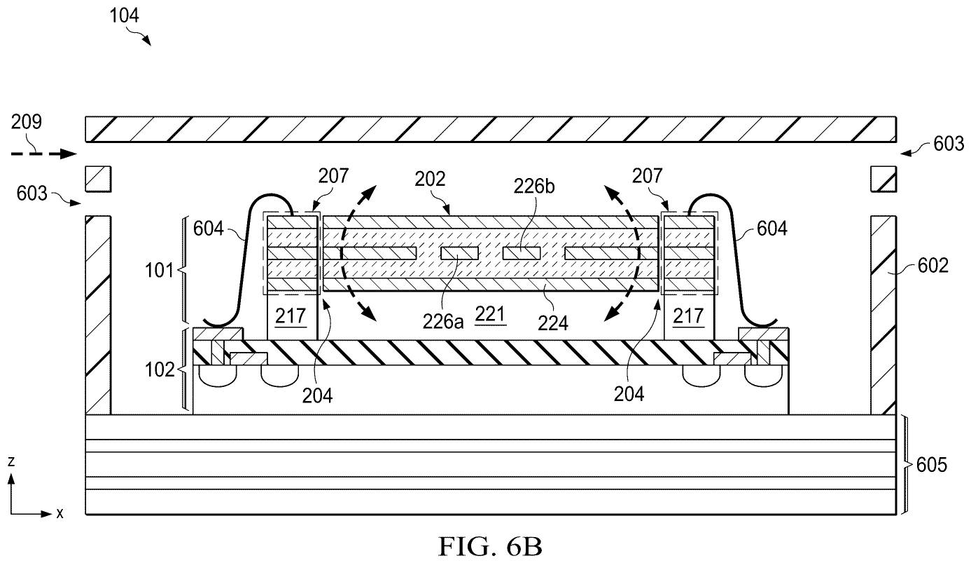

FIG. 6A is a schematic illustrating a side view of audio system 104 where microphone 101 is stacked on a semiconductor die, and a casing has multiple openings on the top of the casing, in accordance with at least one example. Here, cavity 221 is between bottom electrode 224 of microphone 101 and top surface of processing circuitry 102 illustrated as a semiconductor die. In at least one example, pads 204a and 204b are formed over fixed portion 207 and further coupled to processing circuitry 102 through wire bonds 604. In at least one example, processing circuitry 102 is on a printed circuit board (PCB) 605. The stack of processing circuitry 102 and microphone 101 are encased in a case 602. In this example, case 602 has solid side walls and openings 603 on the top. In at least one example openings 603 are configured (e.g., number of openings and/or dimensions of the openings are determined) to allow input pressure from sound 209 to generate differential pressure on cantilever flaps 222a and 222b causing rotational movement of cantilever 222 along the pivot. In at least one example, openings 603 are large enough to avoid viscous damping with air moving through. In one instance, as long as openings 603 are as close as possible to the butterfly structure of directional microphone 101, the directional response is suitable.

FIG. 6B is a schematic illustrating a side view of the audio system where the microphone is stacked on a semiconductor die, and a casing has multiple openings on sides of the casing, in accordance with at least one example. Here, top surface of case 602 is solid (e.g., without opening) while top section of side walls of case 602 have one or more openings 603 to facilitate parallel or in-plane sound to be received by microphone 101, wherein the parallel sound causes differential pressure resulting in rocking motion of cantilever 222.

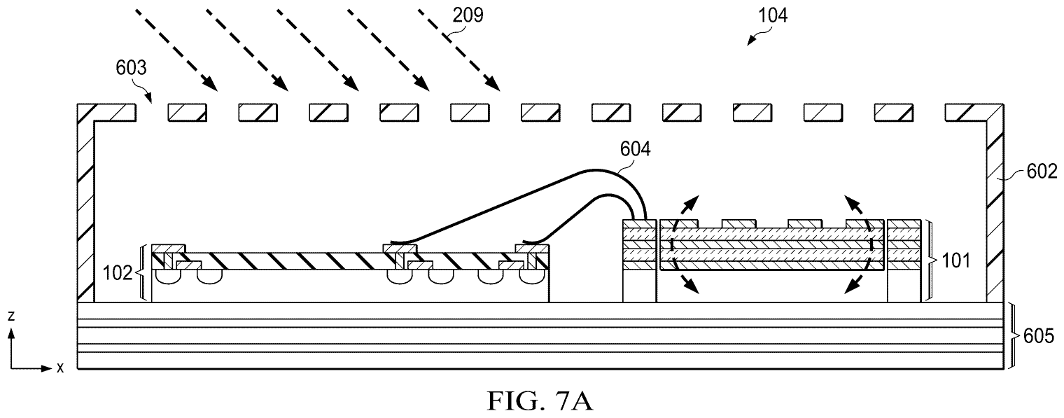

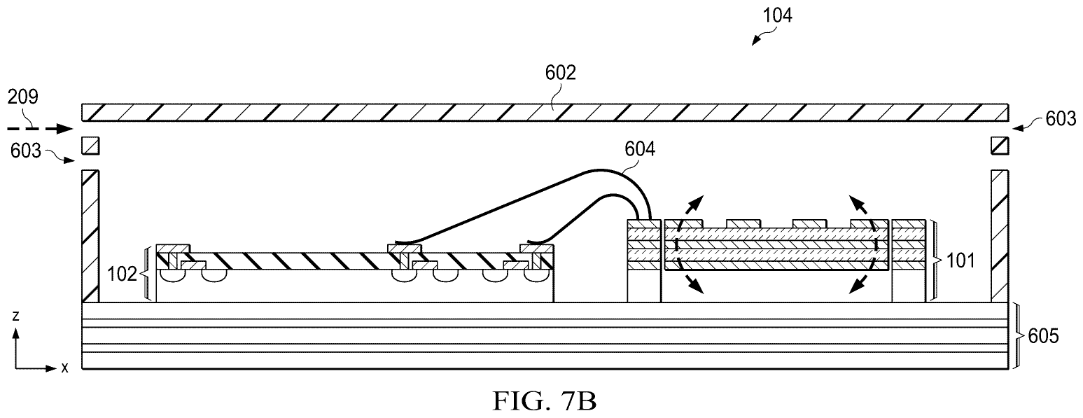

FIG. 7A is a schematic illustrating a side view of the audio system where the microphone is adjacent to a semiconductor die, and a casing has multiple openings on the top of the casing, in accordance with at least one example. In at least one example, the height of audio system 104 can be reduced by placing processing circuitry 102 adjacent to microphone 101 such that both processing circuitry 102 and microphone 101 are on PCB 605. In this example, case 602 has solid side walls and openings 603 on the top. In at least one example, openings 603 are configured (e.g., number of openings and/or dimensions of the openings are determined) to allow input pressure from sound 209 to generate differential pressure on cantilever flaps 222a and 222b causing rotational movement of cantilever along the pivot.

FIG. 7B is a schematic illustrating a side view of the audio system where the microphone is adjacent to a semiconductor die, and a casing has multiple openings on sides of the casing, in accordance with at least one example. Here, top surface of case 602 is solid (e.g., without opening) while top section of side walls of case 602 have one or more openings 603 to facilitate parallel sound to be received by microphone 101, wherein the parallel sound causes differential pressure resulting in rocking motion of cantilever 222.

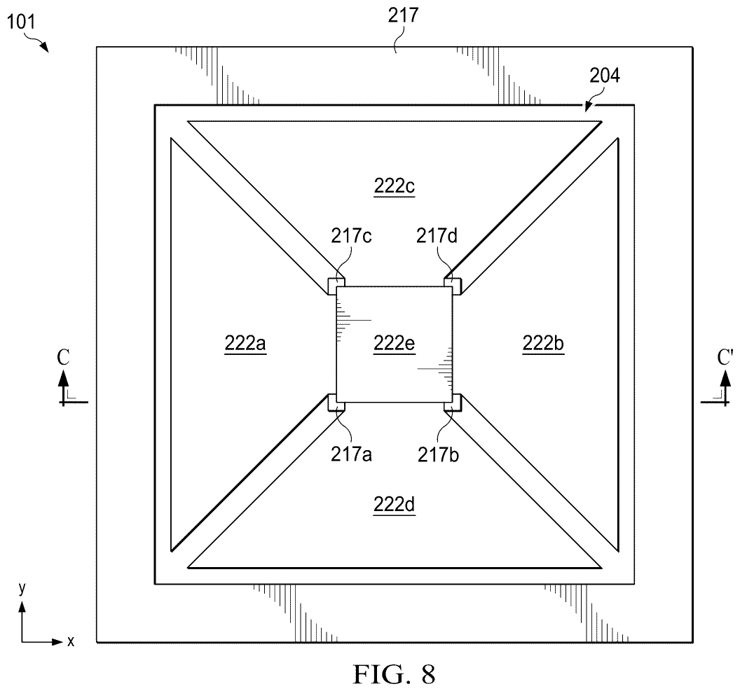

FIG. 8 is a schematic illustrating a top view of an ambient microphone with four symmetrical tapered cantilevers coupled to anchors in a middle portion of the four symmetrical tapered cantilevers, in accordance with at least one example. In at least one example, the ambient microphone is a coupled butterfly shaped microphone along dual axis with a teeter-trotter structure in both x and y axis, supported by x and y pivot on a middle turret. The ambient microphone allows for selected directivity along any in-plane direction based on signal readout.

In at least one example, in-plane sound (e.g., along x or y direction) can be detected by extending the configuration of FIG. 2A. Here, four flaps are shown forming two butterfly shaped membranes, one having first and second flaps 222a and 222b, respectively, and the other having third and fourth flaps 222c and 222d, respectively, orthogonal to first and second flaps 222a and 222b, respectively. Shorter sections of first and second flaps 222a and 222b, respectively, and third and fourth flaps 222c and 222d, respectively, are coupled at middle region 222e and anchored by four corner anchors 217a, 217b, 217c, and 217d. Anchors 217a, 217b, 217c, and 217d allow first and second flaps 222a and 222b to bend or rotate depending on direction of input pressure. Likewise, anchors 217a, 217b, 217c, and 217d allow third and fourth flaps 222c and 222d to bend or rotate depending on direction of input pressure. First, second, third, and fourth flaps 222a, 222b, 222c, and 222d, respectively, comprise bimorph piezoelectric structures with top, middle, and bottom electrodes and piezoelectric material between the electrodes. The electrodes in each flap are symmetric at the four different cantilever flaps. In at least one example, ambient microphone can be configured to be directional at any direction. For instance, one direction sensitivity (along x-direction) can be facilitated over another direction (along y-direction) by adding mass or weight on the end of pair of flaps for that direction.

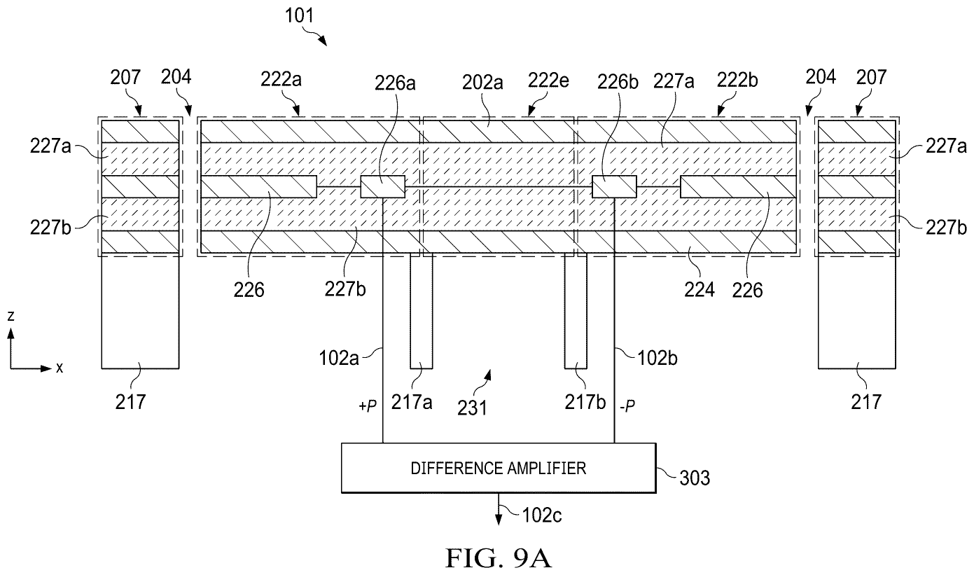

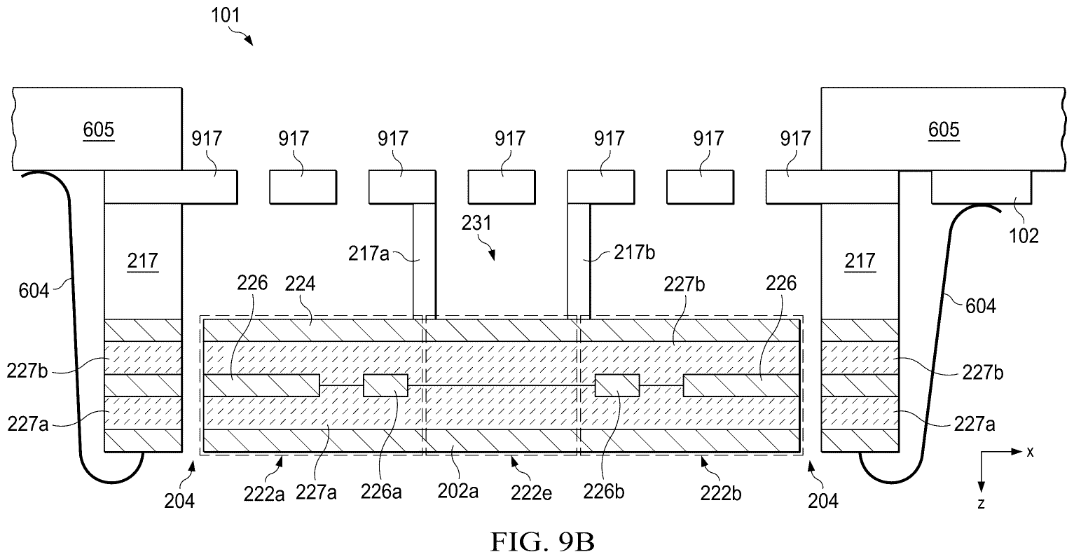

FIG. 9A is a schematic illustrating a side view of the ambient microphone of FIG. 8, in accordance with at least one example. The cross-section of the ambient microphone of FIG. 8 is similar to the cross-section of the directional microphone of FIG. 2A in structure and function. Here, the pivot is stretched over four anchors 217a, 217b, 217c, and 271d that comprise substrate 217 or fixed portion 207. Fixed portion 207 comprises a stack of piezoelectric material, which may be similar to the piezoelectric stack of the cantilever that form first, second, third, and fourth flaps 222a, 222b, 222c, and 222d, respectively, of the ambient microphone. The cross-section shows two of the four anchors.

In at least one example, bending motion of first, second, third, and fourth flaps 222a, 222b, 222c, and 222d, respectively, is restricted by making middle region 222e stiffer. One way to restrict the bending motion is to add a mass over middle region 222e between the anchors. In at least one example, the mass is a silicon mass, a metal layer, a bimorph or a unimorph piezoelectric material. In at least one example, rotation motion is facilitated over bending motion by adding mass at the distal ends of first, second, third, and fourth flaps 222a, 222b, 222c, and 222d, respectively.

FIG. 9B is a schematic illustrating a side view of the ambient microphone of FIG. 8 with an opening in a printed circuit board for passage of sound, in accordance with at least one example. In at least one example, substrate 217 and anchors 217a, 217b, 217c, and 217d sit on a layer of substrate 917 with holes 932. Holes 932 allow for sound to reach first, second, third, and fourth flaps 222a, 222b, 222c, and 222d, respectively, via cavity 231. In at least one example, PCB 605 includes a cavity 931 under the ambient microphone. In this case, sound pressure interacts with first, second, third, and fourth flaps 222a, 222b, 222c, and 222d, respectively, from the bottom rather than the top. A casing may enclose the structure of FIG. 9B. In at least one example, the casing may include holes at the bottom allowing sound to pass through cavity 931 and no holes on the side walls.

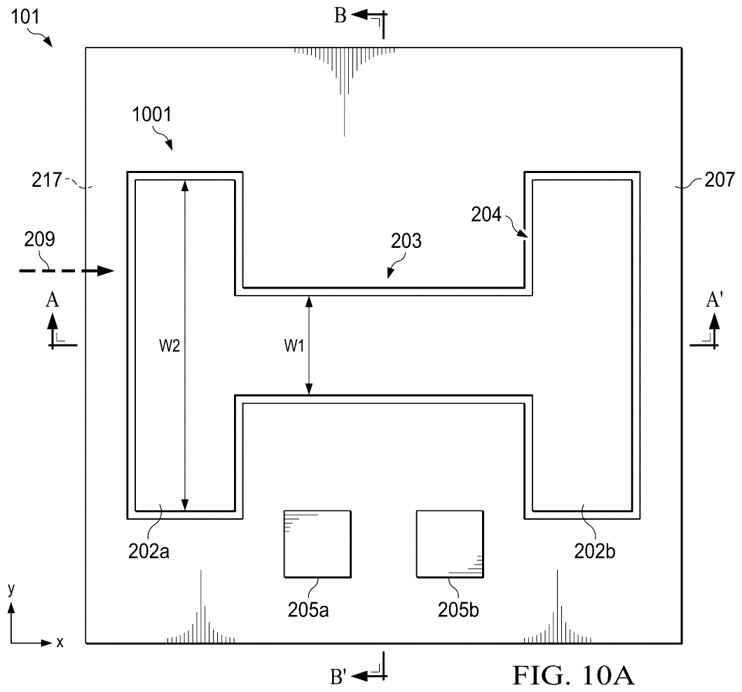

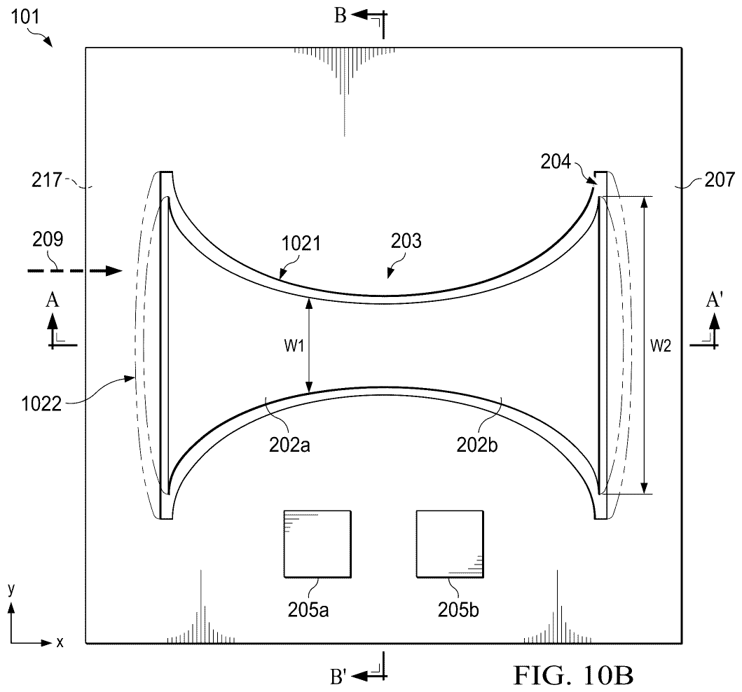

FIG. 10A is a schematic illustrating a top view of a directional microphone with hammerhead cantilevers anchored in a middle portion of the hammerhead cantilevers, in accordance with at least one example. FIG. 10B is a schematic illustrating a top view of a directional microphone with curvingly tapered cantilevers anchored in a middle portion of the curvingly tapered cantilevers, in accordance with at least one example. The butterfly shaped membrane of the directional microphone of FIG. 10A has a hammerhead 1001 where the larger side of the flaps are rectangular when W1 is less than W2, as shown. In at least one example, the butterfly shaped membrane of the directional microphone of FIG. 10B has curved side edges 1021 and straight or curved distal edges 1022. Functionally, the directional microphone here operates same as the directional microphone discussed with reference to FIGS. 2A-E.

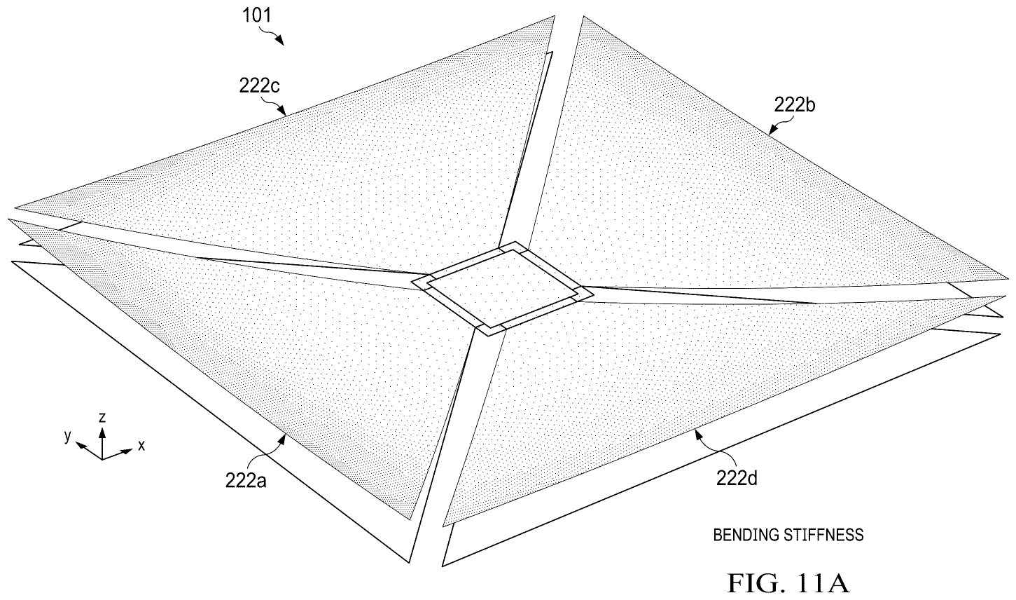

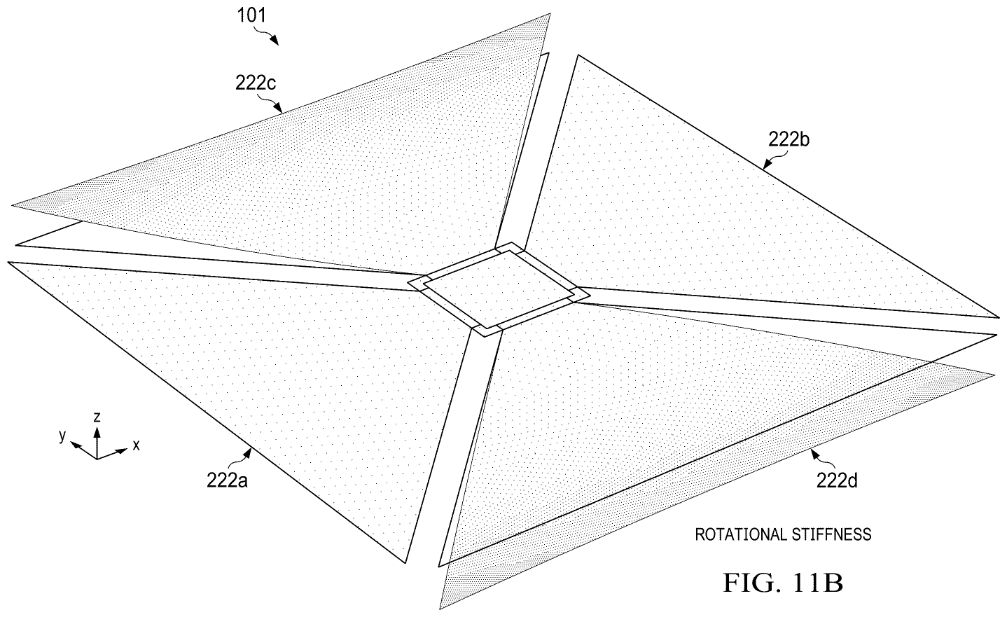

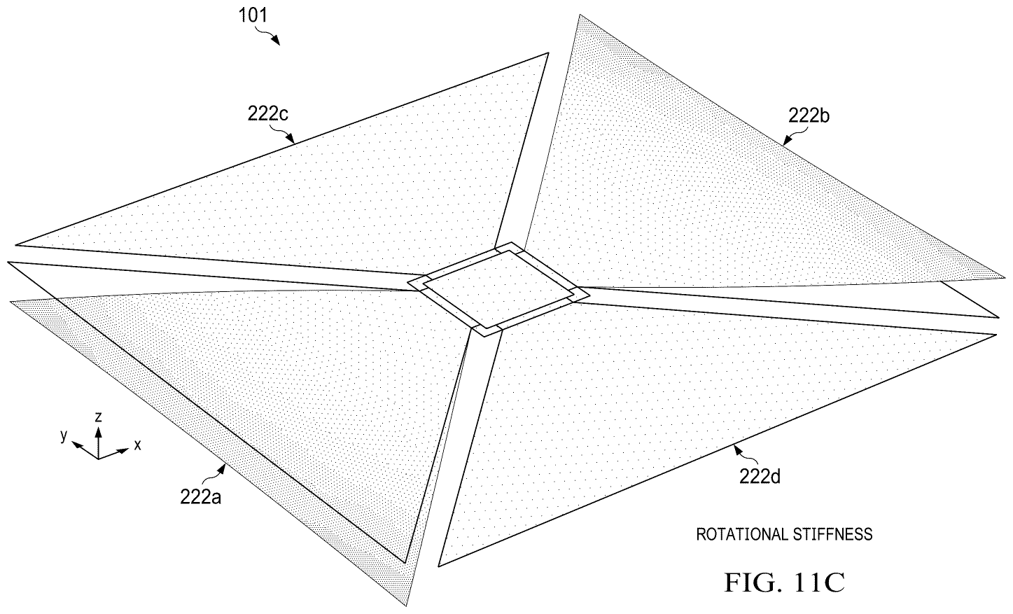

FIGS. 11A-C are schematics of the ambient microphone showing bending and rotational stiffness, in accordance with some examples. Input sound pressure falling perpendicular to first, second, third, and fourth flaps 222a, 222b, 222c, and 222d, respectively, in the z-direction cause first, second, third, and fourth flaps 222a, 222b, 222c, and 222d, respectively, to bend, and this bending is illustrated by FIG. 11A. Input sound pressure parallel to first, second, third, and fourth flaps 222a, 222b, 222c, and 222d, respectively, and in the x-direction of the butterfly shaped membranes cause first and second flaps 222a and 222b, respectively, to rotate while third and fourth flaps 222c and 222d, respectively, remain at their initial state as illustrated by FIG. 11B. Input sound pressure parallel to first, second, third, and fourth flaps 222a, 222b, 222c, and 222d, respectively, in the y-direction of the butterfly shaped membranes cause third and fourth flaps 222c and 222d, respectively, to rotate while first and second flaps 222a and 222b, respectively, remain at their initial state as illustrated by FIG. 11C.

Following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementation without changing the scope of disclosure.

Example 1 is an apparatus comprising: a substrate including a cavity and first and second anchors; and a cantilever including a first portion, a second portion, and a third portion, the first portion coupled between the second and third portions, the first portion coupled to the first and second anchors and suspended over the cavity, and a length of the first portion along a dimension which is shorter than respective lengths of the second and third portions along the dimension.

Example 2 is an apparatus according to any example herein, in particular example 1, wherein each of the second and third portions has a respective shape that tapers towards the first portion.

Example 3 is an apparatus according to any example herein, in particular example 1, wherein each of the second and third portions has a respective shape that tapers towards the first portion.

Example 4 is an apparatus according to any example herein, in particular example 1, wherein each of the second and third portions have curved edges extending towards the first portion.

Example 5 is an apparatus according to any example herein, in particular example 1, wherein a thickness of the first portion is larger than respective thicknesses of the second and third portions.

Example 6 is an apparatus according to any example herein, in particular example 1, wherein a thickness of the first portion is smaller than respective thicknesses of distal ends of the second and third portions.

Example 7 is an apparatus according to any example herein, in particular example 1, wherein: the first portion is coupled between the second and third portions along a first axis; the substrate includes a third anchor and a fourth anchor coupled to the first portion; the cantilever includes a fourth portion and a fifth portion, the first portion coupled between the fourth and fifth portions along a second axis; and the first axis and the second axis are orthogonal to each other.

Example 8 is an apparatus according to any example herein, in particular example 6, wherein each of the fourth and fifth portions has a respective shape that tapers towards the first portion.

Example 9 is an apparatus according to any example herein, in particular example 1, wherein the cantilever includes a piezoelectric material, a first electrode layer, and a second electrode layer.

Example 10 is an apparatus according to any example herein, in particular example 8, wherein the cantilever includes a piezoelectric bimorph having the first electrode layer, a third electrode layer, and the second electrode layer between the first and third electrode layers.

Example 11 is an apparatus according to any example herein, in particular example 8, wherein the first and second anchors form a pivot, wherein at least one of the first or second electrodes includes a first electrode portion and a second electrode portion on opposite sides of the pivot and spaced apart from each other.

Example 12 is an apparatus according to any example herein, in particular example 10, further including a difference amplifier having a first input, a second input and an output, wherein the first input is coupled to the first electrode portion, and wherein the second input is coupled to the second electrode portion.

Example 13 is an apparatus according to any example herein, in particular example 11, further comprising a first die, a second die, and a package substrate on which the first and second dies are mounted, wherein the substrate, the first and second anchors, and the cantilever is on the first die, and the difference amplifier is on the second die.

Example 14 is an apparatus according to any example herein, in particular example 12, wherein the first die and the second die form a stack on the package substrate.

Example 15 is an apparatus according to any example herein, in particular example 12, wherein the first die and the second die are laterally adjacent to each other on the package substrate.

Example 16 is an apparatus according to any example herein, in particular example 12, further comprising a case on the package substrate enclosing the first and second dies, wherein the case includes multiple openings.

Example 17 is an apparatus according to any example herein, in particular example 15, wherein the openings are over the first dic.

Example 18 is an apparatus according to any example herein, in particular example 15, wherein the openings are on a side of the first dic.

Example 19 is an apparatus according to any example herein, in particular example 1, which further includes a difference amplifier coupled to the cantilever, wherein the cantilever and the difference amplifier are configured as a directional microphone.

Example 20 is a packaged integrated circuit including: a package substrate; a die on the package substrate, the die including: a first substrate including a cavity and first and second anchors; a cantilever including a first portion, a second portion, and a third portion, the first portion coupled between the second and third portions, the first portion coupled to the first and second anchors and suspended over the cavity, and a length of the first portion along a dimension is shorter than respective lengths of the second and third portions along the dimension; and a case on the package substrate and enclosing the die, the case including multiple openings.

Example 21 is a packaged integrated circuit according to any claim herein, in particular example 19, wherein each of the second and third portions has a respective shape that tapers towards the first portion.

Example 22 is a packaged integrated circuit according to any claim herein, in particular example 19, wherein each of the second and third portions have curved edges extending towards the first portion.

Example 23 is a packaged integrated circuit according to any claim herein, in particular example 19, wherein a thickness of the first portion is larger than respective thicknesses of the second and third portions.

Example 24 is a packaged integrated circuit according to any claim herein, in particular example 19, wherein a thickness of the first portion is smaller than respective thicknesses of distal ends of the second and third portions.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics, or semiconductor components.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be in depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/−10 percent of that parameter or, if the parameter is zero, a reasonable range of values around zero.

What is claimed is:

1. An apparatus comprising:
a substrate including a cavity and first and second anchors;
a cantilever including a first portion, a second portion, and a third portion, the first portion coupled between the second and third portions, the first portion coupled to the first and second anchors and suspended over the cavity, and a length of the first portion along a dimension is shorter than respective lengths of the second and third portions along the dimension.

2. The apparatus of claim 1, wherein each of the second and third portions have a respective shape that tapers towards the first portion.

3. The apparatus of claim 1, wherein each of the second and third portions have curved edges extending towards the first portion.

4. The apparatus of claim 1, wherein a thickness of the first portion is larger than respective thicknesses of the second and third portions.

5. The apparatus of claim 1, wherein a thickness of the first portion is smaller than respective thicknesses of distal ends of the second and third portions.

6. The apparatus of claim 1, wherein:
the first portion is coupled between the second and third portions along a first axis;
the substrate includes a third anchor and a fourth anchor coupled to the first portion;
the cantilever includes a fourth portion and a fifth portion, and the first portion is coupled between the fourth and fifth portions along a second axis; and
the first axis and the second axis are orthogonal to each other.

7. The apparatus of claim 6, wherein each of the fourth and fifth portions has a respective shape that tapers towards the first portion.

8. The apparatus of claim 1, wherein the cantilever includes a piezoelectric material, a first electrode layer, and a second electrode layer.

9. The apparatus of claim 8, wherein the cantilever includes a piezoelectric bimorph having the first electrode layer, a third electrode layer, and the second electrode layer between the first and third electrode layers.

10. The apparatus of claim 8, wherein the first and second anchors form a pivot, wherein at least one of the first or second electrodes include a first electrode portion and a second electrode portion on opposite sides of the pivot and spaced apart from each other.

11. The apparatus of claim 10, further including a difference amplifier having a first input, a second input, and an output, wherein the first input is coupled to the first electrode portion, and wherein the second input is coupled to the second electrode portion.

12. The apparatus of claim 11, further comprising a first die, a second die, and a package substrate on which the first and second dies are mounted, wherein the substrate, the first and second anchors, and the cantilever is on the first die, and the difference amplifier is on the second die.

13. The apparatus of claim 12, wherein the first die and the second die form a stack on the package substrate.

14. The apparatus of claim 12, wherein the first die and the second die are laterally adjacent to each other on the package substrate.

15. The apparatus of claim 12, further comprising a case on the package substrate enclosing the first and second dies, wherein the case includes multiple openings.

16. The apparatus of claim 15, wherein the openings are over the first die.

17. The apparatus of claim 15, wherein the openings are on a side of the first die.

18. The apparatus of claim 1 further includes a difference amplifier coupled to the cantilever, wherein the cantilever and the difference amplifier are configured as a directional microphone.

19. A packaged integrated circuit including:
a package substrate;
a die on the package substrate, the die including:
a first substrate including a cavity and first and second anchors;
a cantilever including a first portion, a second portion, and a third portion, the first portion coupled between the second and third portions, the first portion coupled to the first and second anchors and suspended over the cavity, and a length of the first portion along a dimension is shorter than respective lengths of the second and third portions along the dimension; and
a case on the package substrate and enclosing the die, the case including multiple openings.

20. The packaged integrated circuit of claim 19, wherein each of the second and third portions has a respective shape that tapers towards the first portion.

21. The packaged integrated circuit of claim 19, wherein each of the second and third portions have curved edges extending towards the first portion.

22. The packaged integrated circuit of claim 19, wherein a thickness of the first portion is larger than respective thicknesses of the second and third portions.

23. The packaged integrated circuit of claim 19, wherein a thickness of the first portion is smaller than respective thicknesses of distal ends of the second and third portions.
